(19) United States
(12) Patent Application Publication
(10) Pub. No.: US 2023/0309262 A1
(43) Pub. Date: Sep. 28, 2023

(54) FLOW ENHANCEMENT STRUCTURE FOR IMMERSION COOLED ELECTRONIC SYSTEMS

(71) Applicant: Intel Corporation, Santa Clara, CA (US)

(72) Inventors: Liguang DU, Shanghai (CN); Guangying ZHANG, Shanghai (CN); Shaorong ZHOU, Shanghai (CN); David PIDWERBECKI, Portland, OR (US); Chuanlou WANG, Shanghai (CN); Sandeep AHUJA, Portland, OR (US); Mark MACDONALD, Beaverton, OR (US); Sung Ki KIM, Portland, OR (US); Xiang QUE, Suzhou (CN); Haifeng GONG, Shanghai (CN); Jessica GULLBRAND, Brightwood, OR (US); Drew DAMM, Beaverton, OR (US); Eric D. MCAFEE, Portland, OR (US); Suchismita SARANGI, Lindstrom, MN (US)

(73) Assignee: Intel Corporation, Santa Clara, CA (US)

(21) Appl. No.: 18/203,904

(22) Filed: May 31, 2023

(30) Foreign Application Priority Data
May 12, 2023 (WO) PCT/CN2023/093755

(51) Int. Cl. H05K 7/20

(52) U.S. Cl. CPC H05K 7/20272; H05K 7/20236; H05K 7/2039; H05K 7/20772

(57) ABSTRACT

An apparatus is described that includes a flow enhancement structure to enhance a flow of immersion bath liquid specifically through space between fins of a heat sink and/or across a base of a heat sink.

### CLAIM OF PRIORITY

The present application claims the benefit of priority to Patent Cooperation Treaty (PCT) Application No. PCT/CN2023/093755, filed May 12, 2023, the entire content of which is incorporated herein by reference.

### BACKGROUND OF THE INVENTION

With the increased performance and power consumption of high performance computing environments (such as data centers), system designers are continually seeking ways to improve the cooling technology of the underlying electronic components that generate heat.

### BRIEF DESCRIPTION OF THE DRAWINGS

FIG. 1 depicts an immersion cooling system;

FIGS. 2a and 2b depict circuit boards immersed in an immersion chamber;

FIG. 3 shows a printed circuit board with a flow enhancement structure in the vicinity of the fins of a heat sink;

FIGS. 4a, 4b, 4c and 4d depict an electronic unit assembly with a flow enhancement structure in the vicinity of the fins of a heat sink;

FIGS. 5a, 5b, 5c and 5d pertain to a flow enhancement structure that also acts as a CDU return flow intake;

FIGS. 6a, 6b and 6c pertain to a flow enhancement structure that generates bubbles in the vicinity of the fins of a heat sink;

FIG. 7 shows a data center environment.

### DETAILED DESCRIPTION

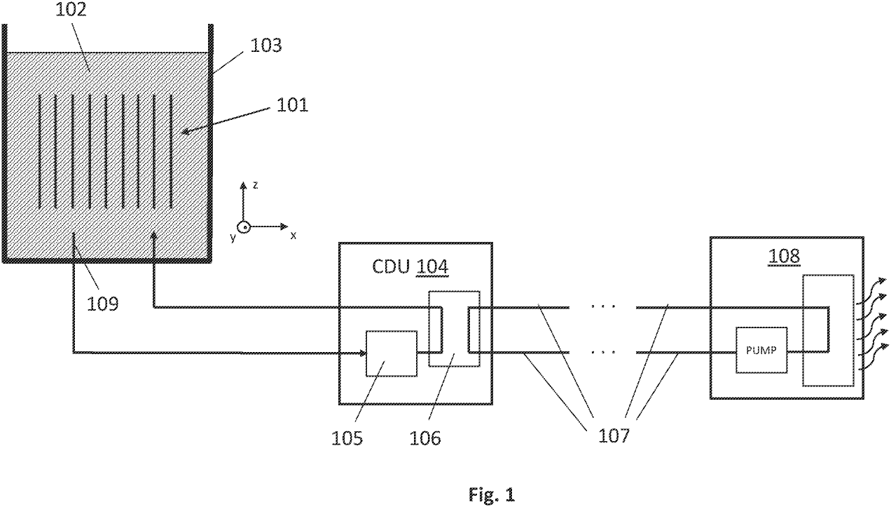

FIG. 1 depicts an immersion cooling system. As observed in FIG. 1, a plurality of electronic circuit boards 101 are immersed in a dielectric liquid 102 that electrically isolates the exposed electrical nodes of the electronic circuit boards 101 and their respective electronic components (FIG. 1 depicts a side view of the circuit boards 101 oriented vertically within the liquid 102). The electronic components, when in operation, generate heat which is transferred to the liquid 102. The liquid 102 has a higher specific heat than air which enables heat to be removed from the electrical components more effectively than would otherwise be achievable in an air-cooled environment.

An immersion bath chamber 103 is fluidically coupled to a coolant distribution unit (CDU) 104 that includes a pump 105 and heat exchanger 106. During continued operation of the electronic components, the liquid’s temperature will rise as a consequence of the heat it receives from the operating electronics. The pump 105 draws the warmed liquid 102 from the immersion bath chamber 103 to the heat exchanger 106. The heat exchanger 106 transfers heat from the warmed fluid to a secondary liquid within a secondary cooling loop 107 that is fluidically coupled to a cooling tower and/or chilling unit 108. The removal of the heat from the liquid 102 by the heat exchanger 106 reduces the temperature of the liquid which is then returned to the chamber 103 as cooled liquid.

In a high computing environment, such as a data center, the respective CDUs of multiple immersion bath chambers are coupled to the secondary loop 107, and, the cooling tower and/or chilling unit 108 removes the heat generated by the electronics within the multiple immersion bath chambers from the data center.

With the increasing performance and corresponding heat dissipation of the electronic components within the immersion bath 102, engineers and technicians are continually seeking ways to improve the efficiency of the thermal transfer from the circuit boards’ respective electronic components to the immersion bath liquid 102.

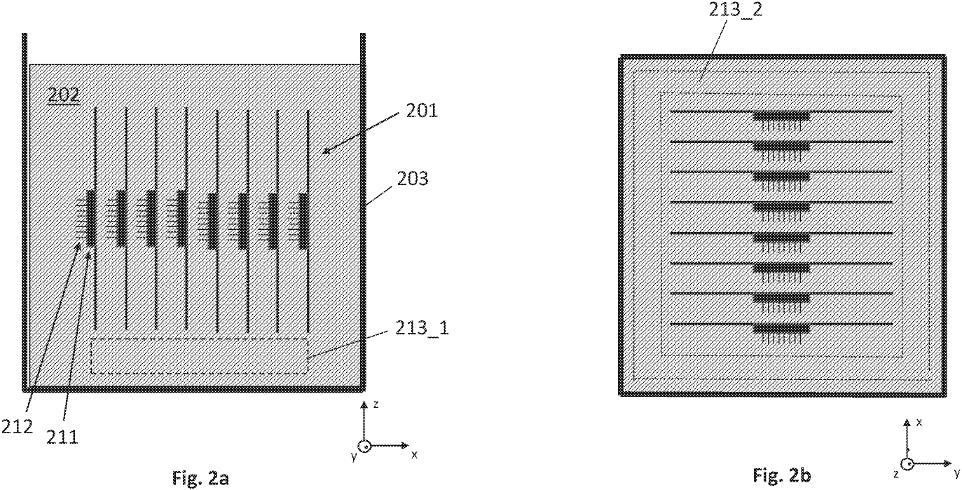

FIGS. 2a and 2b depict a plurality of circuit boards 201 immersed within a liquid 202 within an immersion bath chamber 203 (FIG. 2a shows a side view whereas FIG. 2b shows a top-down view). Notably, the circuit boards 201 are vertically oriented such that the respective faces of the high-performance semiconductor chip packages, and the fins 212 of the heat sinks 211 that are coupled to them, are normal to the horizontal x axis (for ease of illustration, each of the circuit boards 201 include only one high performance chip package and corresponding heat sink).

Ideally, the immersion bath liquid 202 exhibits a high rate of fluid flow through the heat sink fins 212 so that the large amounts of heat generated by the one or more semiconductor chips that are operating within the underlying chip package can be efficiently transferred to the immersion bath 202. Unfortunately, referring to FIG. 2b, the particular arrangement of circuit boards imposes impediments to the creation of such currents.

Firstly, horizontal flow of cooled fluid along the x axis is essentially blocked by the circuit boards 201. Secondly, with the chamber walls, the circuit boards 201 and the circuit boards’ respective electronics and packaging introducing large surface areas that the fluid 202 is to flow over, the fluid 202 experiences viscosity forces that resist its flow throughout the chamber 203, generally (the viscosity forces are proportional to the surface areas of the chamber walls, the circuit boards 201 and the circuit boards’ respective electronics and packaging).

Thirdly, to the extent attempts have been made to induce high velocity currents that run horizontally along the y axis or along the vertical z axis, such attempts have placed various structures and/or components (e.g., baffles, jets) in peripheral regions 213_1, 213_2 outside the circuit boards 201. Unfortunately, with the currents being directed toward the heat sinks 211 from the periphery 213_1, 213_2, the heat sinks 211 can impose flow impedances that cause the currents to flow around the heat sinks 211 rather than through their fins 212.

Finally, the immersion bath liquid 202 has appreciable density and corresponding mass that causes the fluid 202 to experience downward (-z) gravitational forces that act against upward (buoyant) fluid flow in the + z direction. The lack of upward fluid flow, combined with the aforementioned viscous forces, causes flow stagnations and re-circulations within the chamber 203, which, in turn, result in insufficient fluid flow (upward or otherwise) through the heat sink fins 212.

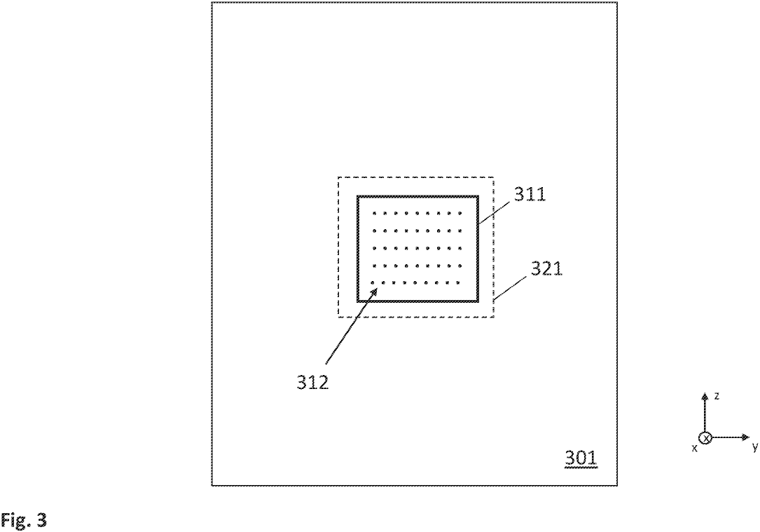

A solution, referring to FIG. 3, is to place a flow enhancement structure 321 in the vicinity of a heat sink 311 that creates a high velocity fluid flow through the space between heat sink’s fins 312 (which can also be stated as “through the fins”). With a flow enhancement structure 321 positioned in the vicinity of the heat sink 311 and/or the heat sink’s fins 312, the higher velocity fluidic currents that are created by the enhancement structure 321 will flow through the heat sink’s fins 312 thereby improving the thermal transfer efficiency from the fins 312 to the liquid.

Notably, as compared to previous solutions that only direct or increase fluid flow generally over a multitude of components, e.g., from the periphery 213 of an electronic circuit board (as described above with respect to FIGS. 2a and 2b), by contrast, the flow enhancement structure 321 is designed to direct and/or increase fluid flow through the fins 312 of a heat sink 311 specifically.

For ease of illustration, again, only a single heat sink 311 is depicted on the circuit board 301 of FIG. 3. It is pertinent to point out that other circuit boards can have multiple high-performance chip packages and corresponding heat sinks per board. In such instances, a respective flow enhancement structure 321 can exist in the proximity of each heat sink (multiple flow enhancement structures per board), an enlarged flow enhancement structure 321 can be designed to enhance fluid flow through the respective fins of multiple heat sinks, some combination of these, etc. Thus, although the following description largely continues to present a single heat sink per circuit board, the reader should bear in mind that the teachings provided below can be readily extended to other types of circuit boards.

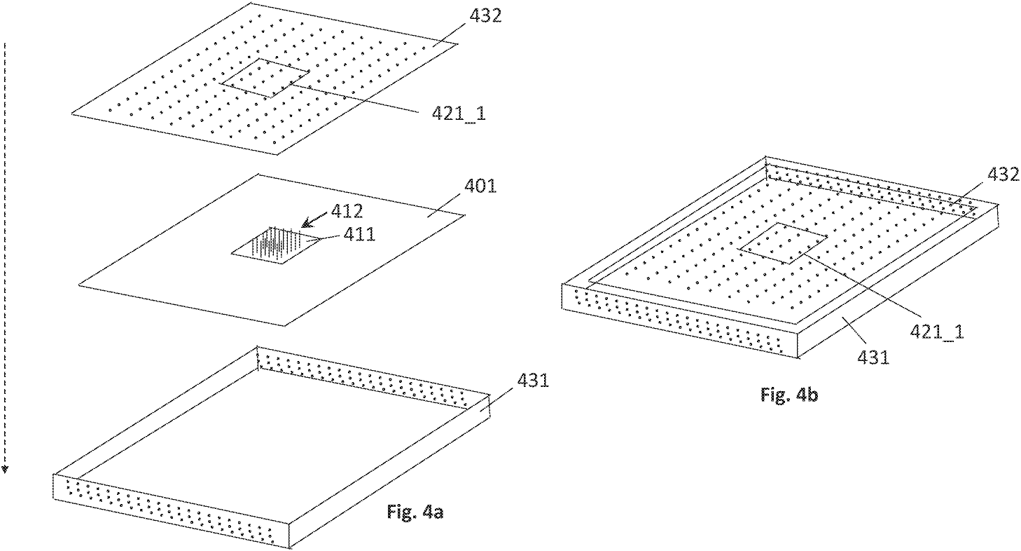

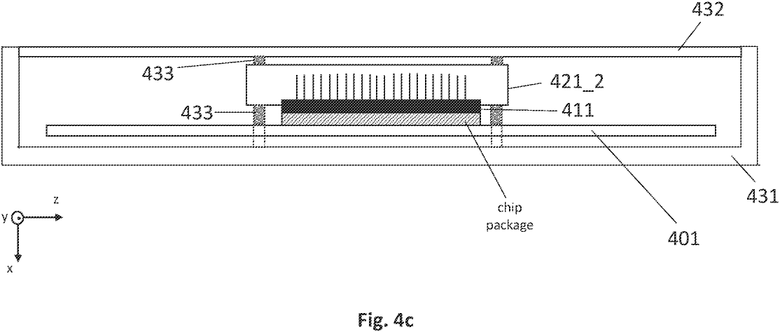

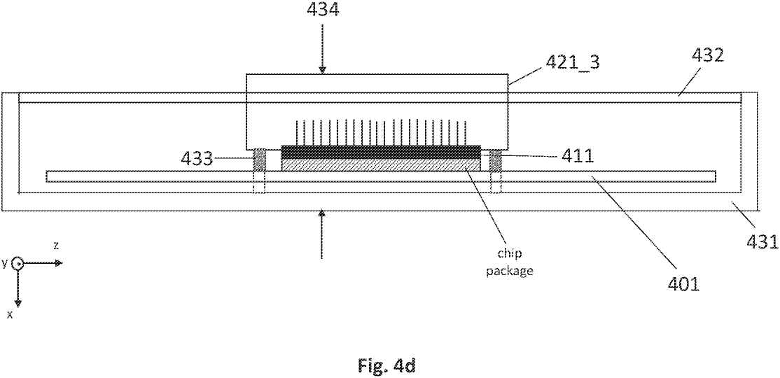

FIGS. 4a through 4d pertain to more detailed embodiments in which a printed circuit board is integrated into a larger assembly 400 before being submersed into the immersion bath. As described in more detail below, the assembly 400 can be a pluggable electronic unit that plugs into an electrical/mechanical interface 433 (or purely mechanical interface) within the immersion bath.

Examples of such pluggable units include a blade server, a CPU unit, an accelerator unit, a memory unit, storage unit, etc. Here, the function of the pluggable electronic unit largely corresponds to the functions that the assembly’s printed circuit board 401 are designed to perform or support (e.g., a computing system in the case of a blade server, one or more multicore processor chips in the case of a CPU unit, one or more accelerators (e.g., one or more neural network chips, artificial intelligence machine learning chips, artificial intelligence inference engine chips, graphics processing unit (GPU) chips, etc.) in the case of an accelerator unit, multiple memory chips (e.g., multiple dual in-line memory modules (DIMMs)) in the case of a memory unit, multiple storage devices (e.g., multiple solid state drives (SSDs)) in the case of a storage unit, etc.).

As observed in FIGS. 4a and 4b the assembly 400 includes a frame 431, the printed circuit board 401 and a cover 432 (FIG. 4a shows an exploded view whereas FIG. 4b shows the completed assembly). The printed circuit board 401 is mounted to the frame 431 (e.g., with screws, bolts or other types of fasteners) and the cover 432 is mounted to the printed circuit board 401 and/or the frame 431.

The frame 431 mechanically supports the printed board 401 whereas the cover 432 mechanically protects the printed circuit board 401 and its electronic components from mechanical shocks/blows that can be imparted to the assembly 400, e.g., during insertion/removal of the assembly to/from the immersion liquid. Notably, the frame 431 and cover 432 have various perforations or other openings that allow fluid to enter the space where the printed circuit board 401 resides so that the electronic components can be cooled by fluidic flow through the assembly 400.

As observed in the particular embodiment of FIGS. 4a and 4b, a flow enhancement structure 421_1 is integrated into the cover 432 of the assembly 400 in the proximity of the heat sink 411 and/or the heat sink’s fins 412.

In still other embodiments, as observed in the side view of FIG. 4c, the flow enhancement structure 421_2 is composed of one or more structures and/or devices that are mechanically secured 433 to the cover 432, printed circuit board 401 and/or frame 431. For example, mechanical structures and/or active electrical components that enhance flow through the heat sink fins 412 are mounted to posts that emanate from the printed circuit board 401 and/or frame 431.

In still other embodiments, the flow enhancement structure is formed from a combination of elements that are formed in the cover 432 and individual elements that are mounted to any/all of the cover 432, printed circuit board 401 and frame 431.

FIG. 4d provides another side view that demonstrates that at least some flow enhancement structures 421_3 can extend beyond the cover 432 in the -x direction. Here, however, in various embodiments, the “height” 234 of the overall assembly along the x axis remains within, e.g., an industry standard dimension that specifies a pluggable unit’s maximum dimension along the x axis. For example, in the case of pluggable electronic units that are designed to conform to an industry standard format that specifies maximum dimension along the x axis in units of U, the extension of the flow enhancement structure 421_3 beyond the cover 432 does not cause the assembly’s widest dimension 234 along the x axis to exceed the applicable standard’s maximum U specified dimension along the x axis.

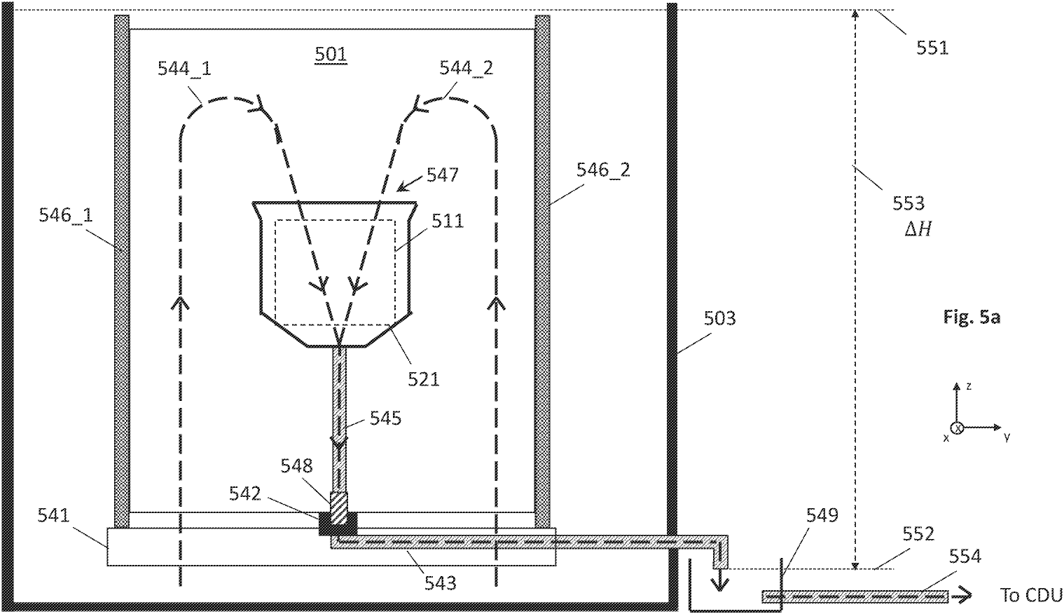

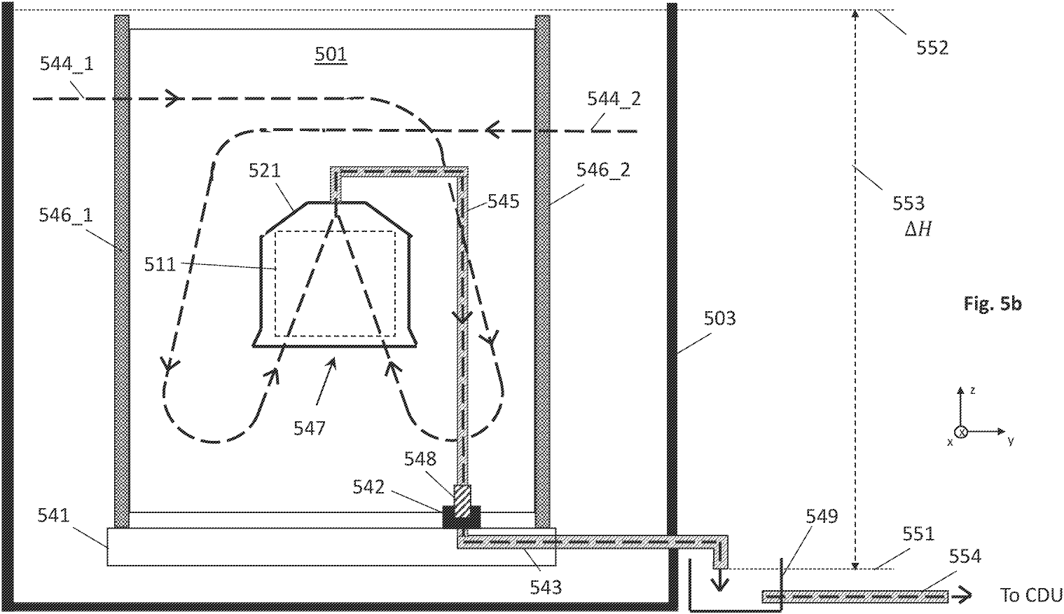

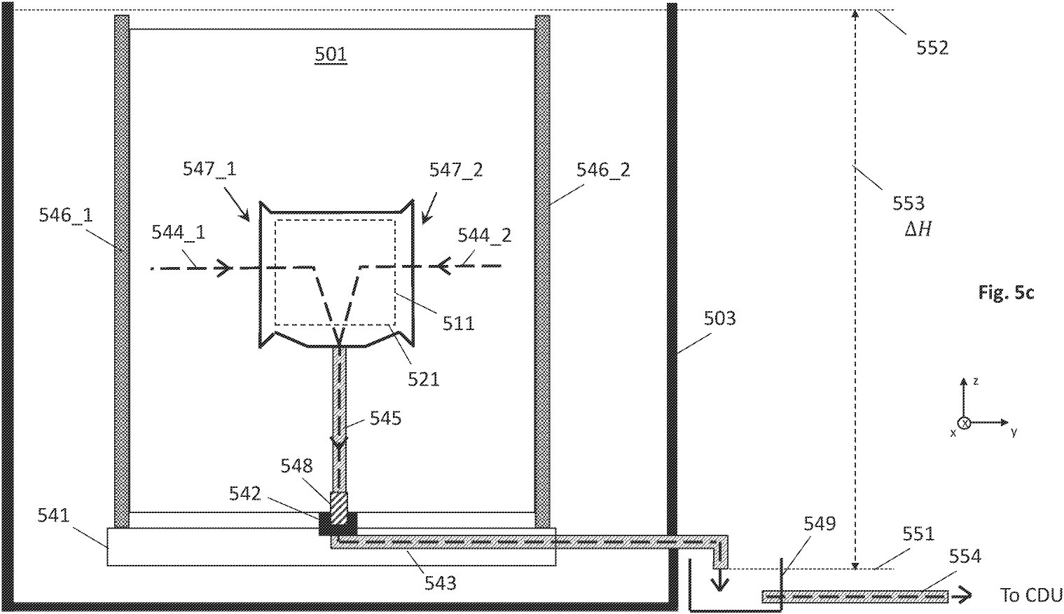

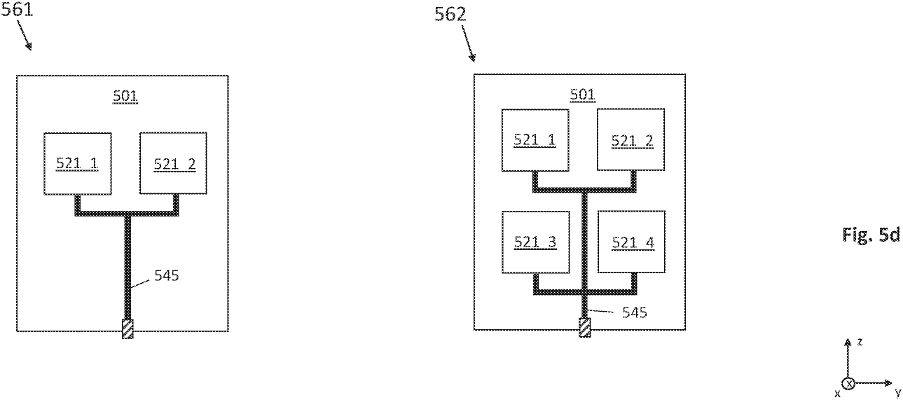

FIGS. 5a through 5d are directed to various embodiments of a flow enhancement structure 521 that not only increases fluid flow rate through the fins of the underlying heat sink 511 but also acts as an intake duct for the liquid coolant return to the CDU. Here, referring to FIG. 5a, the flow enhancement structure 521 is coupled to a fluidic channel 545 (e.g., a hose, a pipe, etc.) that is coupled on an opposite end to a CDU fluidic return channel 543. Referring to both FIG. 5a and FIG. 1, the CDU fluidic return channel 543 corresponds to CDU return channel 109 of FIG. 1, or, a fluidic channel that feeds into the CDU CDU return channel 109 of FIG. 1.

In various embodiments, the immersion bath includes a framework having multiple slots that respective pluggable electronic units can plug into. In the particular embodiment of FIG. 5a, each slot includes a pair of guide rails 546_1, 546_2 that run along the respective sides of the pluggable unit and a backplane 541 that the pluggable unit physically plugs into. The backplane 541 includes a first fluidic connector 542 (e.g., a receptacle) that is aligned with a corresponding second fluidic connector 548 (e.g., a nozzle) that is attached to the end of the fluidic channel 545.

During installation of a pluggable unit, the pluggable unit is entered into the slot from the top of the immersion bath and pressed downward in the -z direction along the guide rails 546_1, 546_2 until it is plugged into the backplane 541. As part of the installation into the slot, the first fluidic connector 542 is connected to the second fluidic connector 548 thereby fluidically coupling the channel 545 that emanates from the flow enhancement structure to CDU return line 543.

During operation of the particular embodiment of FIG. 5a, cooled fluid 544_1, 544_2 from the CDU is injected upward in the +z direction from beneath the pluggable unit. The upward injection induces currents of cooled immersion bath fluid that flow upward over the pluggable unit’s electronics but flow around the flow enhancement structure 521 which covers the heat sink 511 (in the particular embodiment of FIG. 5a, the bottom end of the flow enhancement structure 521 is shaped to cause the upward flow to curve around the structure 521).

The fluid continues to flow 544_1, 544_2 upward above the duct 521. Due to suction from the CDU pump and/or gravity, the immersion coolant flows 544_1, 544_2 are drawn into the intake duct opening 547 of the flow enhancement structure 521. The fluid 544_1, 544_2 then flows through the flow enhancement structure 521 (ideally, with a high fluidic velocity).

Here, the flow enhancement structure 521 is designed as a kind of housing that encompasses the fins of the heat sink of a high performance chip package 511 that resides directly beneath the flow enhancement structure 521. With the immersion coolant 544_1, 544_2 flowing at a high velocity through the flow enhancement structure 521, and with the flow enhancement structure 521 confining the currents 544_1, 544_1 to flow through the space between the fins of the heat sink, heat is transferred from the heat sink fins to the immersion bath flows 544_1, 544_1 with high efficiency (low thermal resistance).

Notably, because the high performance semiconductor chip(s) within the chip package beneath the heat sink 511 generate most of the pluggable unit’s heat, as the currents 544_1, 544_2 flow around the flow enhancement structure 521 immediately after injection into the bath, they do not capture significant heat because they flow through/across electronics that generate significantly less heat than the chip(s) in the high performance chip package beneath the heat sink 511. As such, the temperature of the fluid as it enters the intake duct 547 should be relatively cool (the temperature is only slightly warmed than the temperature of the fluid that enters the immersion bath from the CDU).

As discussed above, higher thermal transfer efficiencies from the heat sink fins to the fluid within the flow enhancement structure 521 is achieved with increasing fluid flow velocity through the structure 521. In order to increase the flow rate through the enhancement structure 521, the draw/suction from the CDU pump can be increased.

In other approaches, however, e.g., to avoid excessively powerful/expensive CDU pump equipment, the flow rate through the flow enhancement structure 521 is increased by establishing a sufficiently large height difference 553 between the upper surface of the coolant within the immersion bath chamber 503 (upper liquid free surface 551) and an opening 552 in the CDU return line 543 (lower liquid free surface 552).

Specifically, as observed in FIG. 5a, the immersion coolant that flows from the immersion bath chamber 503 toward the CDU through return line 543 flows through an opening 552 in the return line 543 and into a plenum 549. The plenum 549 collects the fluid and the CDU pump draws the coolant from the plenum 549 through return line 554 to be cooled.

Importantly, the opening 552 in the return line 543 and an opening in the plenum 549 physically connects the lower liquid free surface 552 to the same ambient as the upper liquid free surface 551. With this arrangement, gravity will cause the rate of fluid flow through the enhancement structure 521 to increase as the height difference 553 between the upper and lower liquid free surfaces 551, 552 increases. As such, for example, extremely high flow rates through the flow enhancement structure 521 can be achieved (e.g., without expensive/powerful CDU pump equipment) by setting the opening 552 in the CDU return line 543 and the plenum 549 sufficiently below the immersion bath chamber 503.

It is pertinent to point out that the specific flow patterns 544_1, 544_2 and intake duct arrangement 547 of FIG. 5a are just one example and that many other flow patterns and intake duct arrangements are possible (e.g., the locations of the inlet/outlet of the liquid flowing to/from the immersion bath chamber and the flow enhancement structure 521 can be various). For example, FIG. 5b shows another approach in which the intake duct 547 faces the bottom of the immersion bath. Here, liquid coolant 544_1, 544_2 is injected along the y axis into the sides of the pluggable unit and flow into the bottom intake duct opening 547 to return back to the CDU. FIG. 5c shows yet another possible arrangement in which there are multiple intake duct openings 547_1, 547_2 on the sides of the flow enhancement structure.

FIG. 5d also shows that the return line from multiple flow enhancement structures on a single pluggable unit can flow feed into one another, e.g., a single fluidic interface at the backplane. Specifically, drawing 561 shows an electronic circuit board 501 having two high-performance chip packages and corresponding flow enhancement structures 521_1, 521, whereas, drawing 562 shows an electronic circuit board having four high-performance chip packages and corresponding flow enhancement structures 521_1, 521_2, 521_3, 521_4. In both drawings 561, 562, the CDU return flow from the set of flow enhancement structures flow into a common CDU return channel 545.

Note that electro-mechanical interfaces can also exist at the backplane 541, and/or, can be coupled to the pluggable unit through the upper surface of the immersion bath 551. In various embodiments (as suggested by FIGS. 5s, 5b and 5c), the backplane 541 is simply a fixture at/near the bottom of an immersion bath chamber 503 that aligns the pluggable unit’s fluidic connector 542 with the corresponding connector 542 that is attached to the CDU return line 543. As such, backplane feature 541 need not extend end-to-end across the width of the electronic unit along the y axis and can instead be, e.g., a simple mechanical fixture that merely holds and aligns connector 542 (and perhaps provides mechanical support for CDU return line 543).

Consistent with the discussion of FIGS. 4a through 4d, any of the flow enhancement structures 521 and/or fluidic channels 545 of FIGS. 5a through 5d discussed above can be: 1) a feature that is designed into the cover 432 of the assembly; 2) a standalone feature that is mounted to the circuit board 401 and/or the frame 431 of the assembly; or, 3) some combination of 1) and 2) above.

In various embodiments, one or more traditional CDU return lines are also coupled to the chamber 503 so that less than all of the CDU return flows through the chamber’s flow enhancement structure(s).

Although the embodiments of FIGS. 5a through 5d have been directed to an approach in which the flow enhancement structure 521 acts as an intake for a CDU return flow, in other embodiments, the flow enhancement structure 521 is coupled to a cooled fluid line from a CDU (with a fluidic channel similar to channel 545) and runs cooled fluid from the CDU through the structure 521 and space between the heat sink fins before the fluid is emitted from the flow enhancement structure to cool components in the immersion bath other than the component that the heat sink fins are coupled to.

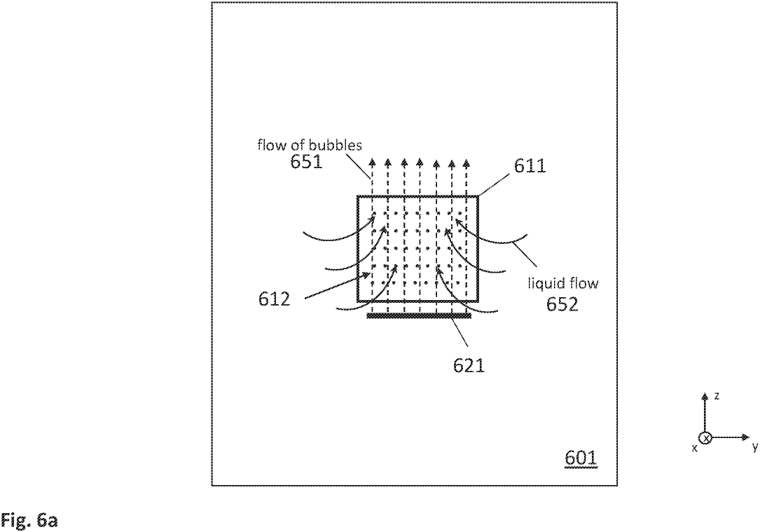

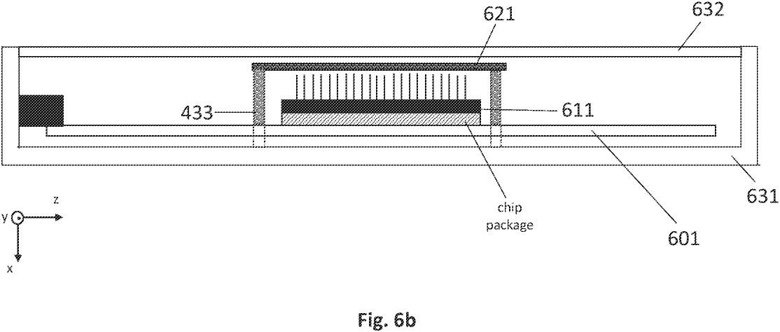

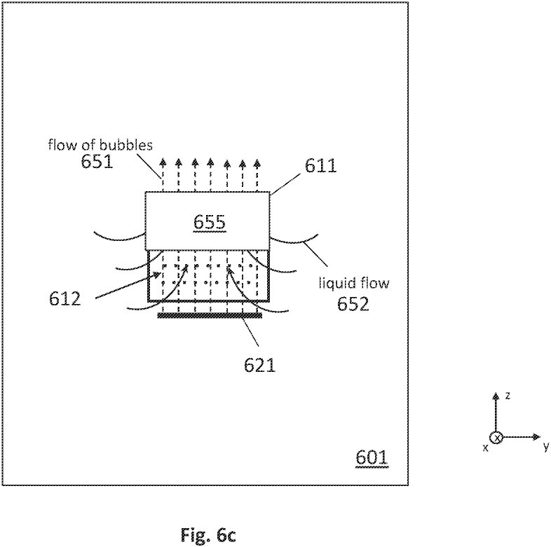

FIGS. 6a through 6c pertain to another approach in which the flow enhancement structure 621 is a bubble generation device that causes bubbles to flow 651 across the fins 612 of the heat sink 611. Here, as described in more detail below, the upward flow 651 of bubbles through the heat sink fins 612 causes an increase in the buoyancy (upward) flow of the coolant liquid through the fins, which, in turn, improves the thermal transfer efficiency from the fins to the liquid.

Specifically, once generated, the bubbles immediately begin to rise or otherwise flow 651 at a high velocity through the space between the heat sink fins 612. Importantly, gaseous pressure within a bubble increases as the diameter/size of the bubble decreases. Thus, small bubbles (e.g., having a diameter within a range 0.1 mm to 10 mm inclusive) having high internal pressures are essentially “non-deformable” within the liquid. The non-deformable property of the smaller bubbles causes them to exhibit an effective “hardness” that creates a wake behind the bubbles as they flow 651 through the liquid. The wake creates a low pressure region behind the bubbles’ that is filled by surrounding liquid 652. Thus, as the bubbles rise upward, liquid is drawn in behind them, which, in turn, effectively increases buoyant fluid flow through the heat sink fins 612.

Additionally, the bubbles can create buoyancy forces near the surfaces of the fins that effectively thin the viscous (momentum) boundary layer and create a more uniform flow through the fin region (increasing flow rate). Where the bubbles are located in the fin region, they effectively decrease the density of the fluid there and significantly increase the buoyance induced flow. As mentioned above, the bubbles will entrain cold fluid to be nearer to the fin surfaces which significantly reduces the thermal resistance (increases the thermal transport/efficiency). These dynamics can exist not only along fin surfaces but also at the root of the fins which can significantly increase the thermal transport.

FIG. 6a shows a first embodiment in which the bubble generation device 621 is placed beneath the heat sink 611 and/or its fins 612 when the corresponding electronic pluggable unit is installed in the immersion chamber. With the bubble generation device 621 generating bubbles beneath the heat sink 611 and/or the heat sink fins 612, the bubbles generated by the device 621 immediately rise through the fin region 612 thereby increasing buoyant flow through the fin region as described just above.

Notably, the bubble generation device 621 can be an active device that requires electrical power to operate. As such, there can be power wiring that runs from the device 621 to the printed circuit board 601 that the heat sink’s semiconductor chip package is mounted to. In various embodiments, a first mechanical connector is mounted to the printed circuit board 601 and the wiring is a feature of the bubble generation device 621. The wiring includes a second mechanical connector that is mated to the first mechanical connector. Alternatively, a reverse approach is applied and the wiring is a feature of the printed circuit board 601.

The bubble generation device 621 can be mounted to any of the printed circuit board 601 (e.g., with a standoff), the pluggable unit’s frame, the pluggable unit’s cover, or any combination of these.

In another or combined approach, as observed in FIG. 6b, the bubble generation device 621 faces the heat sink 611 rather than resides beneath the heat sink 611. In this approach, the bubble generation device 621 directly injects bubbles across most (if not all) of the heat sink fins 612. As an example, the bubble generation device 621 can be a compressed air device that injects streams of bubbles laterally in the +x direction toward the face of the heat sink 611 in the spaces between the fins 612. Initially this will induce a lateral fluid flow across the heat sink fins before the bubble begin to rise in the +z direction and create the aforementioned buoyant flow.

In either of the approaches of FIGS. 6a and 6b, the flow enhancement structure can further includes one or more baffles or other flow guide structures can be placed in the proximity of the heat sink fins 611 to keep the bubbles in the immediate vicinity of the heat sink fins 611. FIG. 6c shows the approach of FIG. 6a but with a partial cover 655 that is placed above the upper half of the heat sink fins 612 (that cover can be integrated within and/or mounted to any of the pluggable unit’s cover, circuit board or frame). The cover prevents bubbles from escaping the immediate vicinity of the top half of the fins 612 in the -x direction. Only half a cover 655 is used to avoid creating too large of a flow impedance for the source of the buoyant liquid flow.

A flow enhancement structure that includes a bubble generation device as described above with respect to FIGS. 6a, 6b and 6c can be integrated wholly or partially into the assembly cover 632 and/or include one or more separate components (e.g., bubble generation device, baffle(s), etc.) that are mounted to the cover, the printed circuit board, the frame or any combination of two or more of these.

The design and operation of the bubble generation device 621 can vary from embodiment to embodiment. According to one approach, the bubble generation device is a frit device that creates bubbles by injecting air through a roughed three dimensional structure (e.g., small carbon rocks as with a typical aquarium filter).

According to another approach, the bubble generation device 621 is a chamber having holes that receives compressed air. The compressed air flows out of the holes forming a stream of bubbles from each of the holes. According to a further approach, the holes are further defined as the hollowed-out inner region of hollow needles that emanate from the chamber. The bubbles emanate from the openings in the needles (akin to smoke from a plurality of chimneys).

In either of these approaches, bubble generation can be promoted by lining the exposed hole surfaces with a coating that affects the ability of the coolant liquid to wet to these surfaces. For example, if bubbles are created at least in part through the flow of coolant liquid into a hole or needle, the hole surfaces (including the exposed hole surfaces within the needles) can be coated with a material that promotes the wetting of the coolant liquid to the hole surfaces. By contrast, if bubbles are created at least in part by preventing the flow of coolant liquid into a hole or needle, the hole surfaces (including the exposed hole surfaces within the needles) can be coated with a material that inhibits the wetting of the coolant liquid to the hole surfaces.

In yet another bubble generation approach, the bubble generation device 621 is peristaltic pump. For example, the bubble generation device 621 includes a hollow chamber covered by a porous membrane. Within the chamber is a cam that continually rotates. The irregular shape of the cam causes air to be compressed against the inner surface of the membrane during a first portion of the cam’s rotation. The compression of the air against the inner surface of the porous membrane causes bubbles to be emitted from the outer surface of the membrane into the surrounding liquid. During a second portion of the cam’s rotation, a new intake of air rushes to the membrane’s inner surface. The process then repeats. In further embodiments, the membrane is elastic. During the second rotation described above, the cam stretches the membrane outward to enhance the air rush intake draw to the inner surface of the membrane.

In another, similar bubble generation approach, bubbles are generated through mechanical agitation (e.g., bending, vibration, etc.). Here, the agitation causes two phases: a first phase in which air is compressed within a chamber and emitted as bubbles from holes in the chamber, and, a second phase in which air is drawn into the chamber. The different phases can correspond, for example, to opposite amplitudes of a periodic mechanical motion (e.g., the chamber is bent in a first direction in the first phase and bent in a second, opposite direction in the second phase). The source of the mechanical agitation can be, e.g., a piezo-electric device, an electro-magnetic device (e.g., a speaker), etc.

In another approach, a multiphase (two phase) flow of air and fluid is created. Then, the multiphase flow is passed through a structure that chops the air of the flow into bubbles that are released into the coolant liquid. For example, a first fluidic channel that is coupled to the coolant fluid and a second fluidic channel that is coupled to a source of external air are joined before a pump which draws flows from both fluidic channels to create the multiphase flow. As the multiphase flow flows through the pump, the pumping action of the pump “chops” the air into bubbles. The flow exits the pump into a chamber with holes. The bubbles pass through the holes into the liquid coolant.

In an alternate approach, the multiphase flow is created by pumping only the coolant liquid through the pump. A venturi device is coupled downstream from the pump output. A venturi device is a fluidic channel having a first section with a wider flow cross-sectional area than a second section with a narrower flow cross-sectional area. In the second section, the fluid’s velocity increases and pressure decreases. An air intake is coupled to the second section, which, having low pressure draws the air into the second section to create a multiphase flow. The high velocity of the fluid in the second section also chops the air into small bubbles. The multiphase flow from the venturi device then passes into a chamber with holes as described above.

In yet another approach, the bubble generation device includes a heat generator that nucleates bubbles by heating the coolant liquid above its boiling point.

With the bubble generation device 621 being an active component, its use can be modulated as part of a larger power management scheme for the pluggable unit it is a component of, and/or, the larger immersion bath that the device 621 is immersed within. For example, to the extent that the rate at which bubbles are generated can be adjusted (e.g., by compressing more or less air into a chamber, adjusting the rotation action of a cam or the pumping action of a pump, adjusting the heat used to nucleate bubbles), adjustments in bubble rate are made, e.g., in view of the power consumption and/or usage of the semiconductor chip(s) within the chip package whose heat sink the bubble generation device 621 is positioned to generate bubbles for the fins of.

Thus, for instance, at one extreme when the chip(s) are in a sleep mode, there is no bubble generation activity, at another extreme when the chip(s) are in a maximum power/usage mode there is maximum bubble generation activity, and, when the chip(s) are operating midway between these two extremes there is bubble generation activity that is less than maximum bubble generation activity. Thus, the aforementioned wiring of the bubble generation device can include or be responsive to control software programs that are executing, e.g., on a processor on the pluggable unit’s circuit board, or some other computer or CPU system.

In the teachings above, note that the heat sink fins have been drawn as needle-like structures that emanate upward from the base of the heat sink. See, for example, fins 312 of FIG. 3 and fins 412 of FIG. 4a. It is pertinent to note that other fin designs are possible, such as planar structures that emanate from the base of the heat sink. In this case (or similar cases), the heat sinks should be oriented such that the fluid flow through the enhancement structure flows through the channels between the fins rather than be blocked by the planar walls of the fins. Additionally, some heat sinks may not include fins, in which case, the teachings above can still be utilized because a flow enhancement structure can be added to enhance fluid flow across the exposed surface of the base of the heat sink.

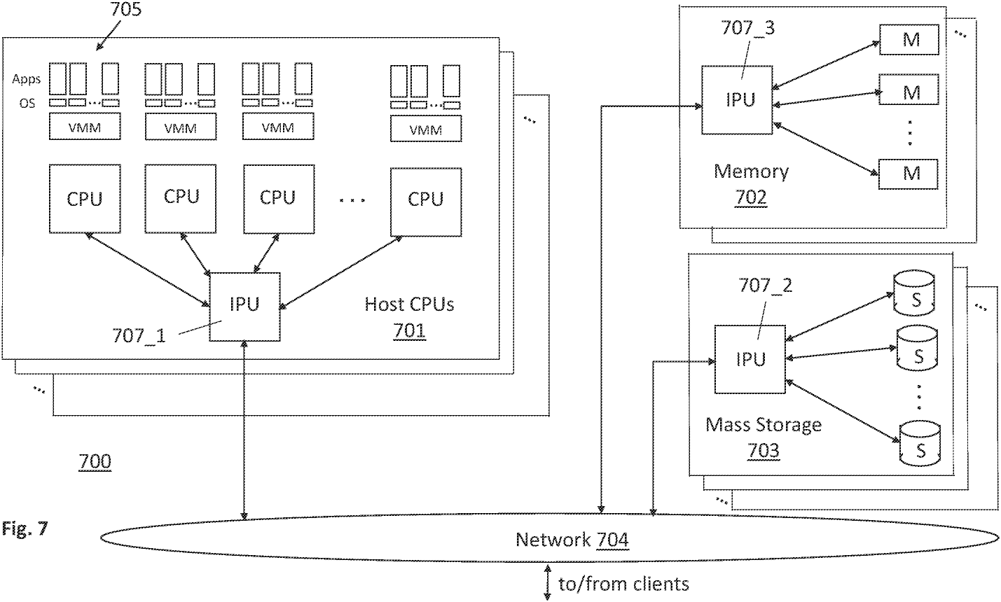

FIG. 7 shows a new, emerging computing environment (e.g., data center) paradigm in which “infrastructure” tasks are offloaded from traditional general purpose “host” CPUs (where application software programs are executed) to an infrastructure processing unit (IPU), data processing unit (DPU) or smart networking interface card (SmartNIC), any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.).

Remote clients invoke/use these applications through temporary network sessions/connections that are established by the data center between the clients and the applications. A recent trend is to strip down the functionality of at least some of the applications into more finer grained, atomic functions (“micro-services”) that are called by client programs as needed. Micro-services typically strive to charge the client/customers based on their actual usage (function call invocations) of the micro-service application.

In order to support the network sessions and/or the applications’ functionality, however, certain underlying computationally intensive and/or trafficking intensive functions (“infrastructure” functions) are performed.

Examples of infrastructure functions include encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), distributed computing remote memory access functions, etc.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators. Moreover, the CPUs, which are typically complex instruction set (CISC) processors, are better utilized executing the processes of a wide variety of different application software programs than the more mundane and/or more focused infrastructure processes.

As such, as observed in FIG. 7, the infrastructure functions are being migrated to an infrastructure processing unit (IPU). FIG. 7 depicts an exemplary data center environment 700 that integrates one or more IPUs 707_1 to offload infrastructure functions from the host CPUs as described above.

As observed in FIG. 7, the exemplary data center environment 700 includes pools 701 of CPU units (e.g., multicore processors) that execute the end-function application software programs 705 that are typically invoked by remotely calling clients. The data center 700 also includes separate memory pools 702 and mass storage pools 703 to assist the executing applications. The CPU, memory storage and mass storage pools 701, 702, 703 are respectively coupled by one or more networks 704.

Notably, each pool 701, 702, 703 has an IPU 707_1, 707_2, 707_3 on its front end or network side. Here, each IPU 707 performs pre-configured infrastructure functions on the inbound (request) packets it receives from the network 704 before delivering the requests to its respective pool’s end function (e.g., executing software in the case of the CPU pool 701, memory in the case of memory pool 702 and storage in the case of mass storage pool 703). As the end functions send certain communications into the network 704, the IPU 707 performs pre-configured infrastructure functions on the outbound communications before transmitting them into the network 704.

Depending on implementation, one or more CPU pools 701, memory pools 702, mass storage pools 703 and network 704 can exist within a single chassis, e.g., as a traditional computing system (e.g., server computer). In a disaggregated computing system implementation, one or more CPU pools 301, memory pools 702, and mass storage pools 703 are, e.g., separate pluggable electronic units (e.g., pluggable CPU units, pluggable memory units (M), pluggable mass storage units (S)). Although not depicted in FIG. 7, an additional accelerator pool could also be coupled to the network 704 through its own IPU similar to the other pools. The accelerator pool can include, e.g., accelerator pluggable units that include any combination of graphics processing units (GPUs), artificial intelligence inference semiconductor chips, artificial intelligence semiconductor chips, image processing accelerators, or other types of accelerators.

Notably, a traditional computing system and/or any of the above mentioned pluggable units can be mechanically configured to be immersed in an immersion bath where the mechanical configuration is designed to increase fluid flow in the vicinity of a heat sink and/or a heat sink’s fins as described at length above.

In various embodiments, the software platform on which the applications 705 are executed include a virtual machine monitor (VMM), or hypervisor, that instantiates multiple virtual machines (VMs). Operating system (OS) instances respectively execute on the VMs and the applications execute on the OS instances. Alternatively or combined, container engines (e.g., Kubernetes container engines) respectively execute on the OS instances. The container engines provide virtualized OS instances and containers respectively execute on the virtualized OS instances. The containers provide isolated execution environment for a suite of applications which can include, applications for micro-services.

Embodiments of the invention may include various processes as set forth above. The processes may be embodied in program code (e.g., machine-executable instructions). The program code, when processed, causes a general-purpose or special-purpose processor to perform the program code’s processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a flow enhancement structure to enhance a flow of immersion bath liquid specifically through space between fins of a heat sink and/or across a base of heat sink.

2. The apparatus of claim 1 wherein the flow enhancement structure comprises an intake duct for a return flow of the immersion bath liquid to a cooling distribution unit.

3. The apparatus of claim 1 wherein the flow enhancement structure is to receive cooled fluid to be emitted into the immersion bath liquid after flowing through the flow enhancement structure.

4. The apparatus of claim 1 wherein the flow enhancement structure comprises a bubble generation device.

5. The apparatus of claim 4 wherein the bubble generation device is to be placed beneath the fins when an electronic circuit board having a semiconductor chip package that is coupled to the heat sink is immersed in the immersion bath liquid.

6. The apparatus of claim 4 wherein the bubble generation device is to be positioned to face the heat sink when an electronic circuit board having a semiconductor chip package that is coupled to the heat sink is immersed in the immersion bath liquid.

7. The apparatus of claim 4 wherein the flow enhancement structure comprises a guide structure to guide where bubbles generated by the bubble generation device flow within the immersion bath liquid.

8. The apparatus of claim 4 wherein the bubble generation device is to generate bubbles having a diameter within a range of 0.1 mm to 10 mm inclusive.

9. An apparatus, comprising:
an electronic assembly comprising:
i) a frame;
ii) an electronic circuit board mounted to the frame;
iii) a semiconductor chip package coupled to the printed circuit board;
iv) a heat sink comprising fins, the heat sink coupled to the semiconductor chip package;
v) a cover mounted to the frame and/or the electronic circuit board;
vi) a flow enhancement structure to enhance a flow of immersion bath liquid specifically through space between the fins and/or across a base of heat sink when the assembly is immersed in the immersion bath liquid.

10. The apparatus of claim 9 wherein the flow enhancement structure comprises an intake duct for a return flow of the immersion bath liquid to a cooling distribution unit, or, is to receive cooled fluid to be emitted into the immersion bath liquid after flowing through the flow enhancement structure.

11. The apparatus of claim 9 wherein the flow enhancement structure comprises a bubble generation device.

12. The apparatus of claim 9 wherein the flow enhancement structure is integrated with the cover.

13. The apparatus of claim 9 wherein the flow enhancement structure is mounted to the electronic circuit board and/or the frame.

14. The apparatus of claim 9 wherein the flow enhancement structure comprises an active device.

15. A data center, comprising:
a network;
a plurality of CPU pools coupled to the network;
a plurality of memory pools coupled to the network;
a plurality of storage pools coupled to the network;
a chamber comprising immersion bath liquid;
an electronic unit within the immersion bath liquid, the electronic unit being a component of one of the CPU pools, the memory pools and the storage pools, the electronic unit comprising a flow enhancement structure to enhance a flow of the immersion bath liquid specifically through space between fins of a heat sink and/or across a base of heat sink that is coupled to a semiconductor chip package of the electronic unit.

16. The data center of claim 15 wherein the flow enhancement structure comprises an intake duct for a return flow of the immersion bath liquid to a cooling distribution unit, or, is to receive cooled fluid to be emitted into the immersion bath liquid after flowing through the flow enhancement structure.

17. The data center of claim 16 wherein the return flow flows through a lower liquid free surface to increase the flow’s rate through the space between the fins.

18. The apparatus of claim 14 wherein the flow enhancement structure comprises an active device.

19. The apparatus of claim 16 wherein the flow enhancement structure comprises a bubble generation device.

20. The apparatus of claim 14 wherein the flow enhancement structure is at least partially integrated with a cover of the electronic unit’s assembly and/or is at least partially mounted to the electronic unit’s electronic circuit board and/or frame.
